(19) United States
(12) Patent Application Publication
(10) Pub. No.: US 2026/0282539 A1
(43) Pub. Date: Sep. 17, 2026

(54) HETEROGENEOUSLY INTEGRATED GA2O3 HIGH-MOBILITY INVERTER AND PREPARATION METHOD THEREOF

(71) Applicant: NANJING UNIVERSITY, Nanjing (CN)

(72) Inventors: Jiandong YE, Nanjing (CN); Yeyun YANG, Nanjing (CN); Fangfang REN, Nanjing (CN); Shulin GU, Nanjing (CN); Rong ZHANG, Nanjing (CN)

(73) Assignee: NANJING UNIVERSITY, Nanjing (CN)

(21) Appl. No.: 19/460,278

(22) Filed: Jan. 26, 2026

(30) Foreign Application Priority Data
Mar. 17, 2025 (CN) 202510309182.9

(51) Int. Cl. H10D 84/86; H10D 30/01; H10D 30/47; H10D 62/80; H10D 84/01; H10D 84/02

(52) U.S. Cl. CPC H10D 84/86; H10D 30/015; H10D 30/475; H10D 62/875; H10D 84/0123; H10D 84/02

(57) ABSTRACT

The present invention discloses a heterogeneously integrated Ga₂O₃ high-mobility inverter and a preparation method thereof. The preparation method includes: preparing an unintentionally doped β-Ga₂O₃ drift layer; sequentially preparing a κ-Ga₂O₃ layer and a κ-(AlₓGa₁₋ₓ)₂O₃ layer; forming an isolation trench; forming a depletion-mode drain metal layer, a depletion-mode source metal layer, an enhancement-mode drain metal layer, and an enhancement-mode source metal layer; forming a depletion-mode gate metal layer; growing a p-type hetero-material layer; forming an enhancement-mode gate metal layer; and jointly connecting the depletion-mode source metal layer and the enhancement-mode drain metal layer to the depletion-mode gate metal layer to obtain the heterogeneously integrated Ga₂O₃ high-mobility inverter.

### CROSS-REFERENCE TO RELATED APPLICATIONS

The present application claims priority benefits to Chinese Patent Application No.202510309182.9 filed on Mar. 17, 2025, which is incorporated herein by reference in its entirety.

### TECHNICAL FIELD

The present invention relates to the technical field of microelectronics, and in particular to a heterogeneously integrated Ga₂O₃ high-mobility inverter and a preparation method thereof.

### BACKGROUND

Gallium oxide (Ga₂O₃) materials possess advantages such as a large band gap and high breakdown field strength. They are superior to semiconductor materials like Si (1.12 eV), SiC (3.3 eV), and GaN (3.4 eV), and become one of the third-generation semiconductor materials that currently attract significant attention from both academic and industrial communities.

Ga₂O₃ has five polymorphs, namely α, β, γ, δ, and ε (κ), exhibiting abundant physical and chemical properties. Among them, β-Ga₂O₃ possesses excellent thermal stability. Its monocrystalline substrates can be grown by a melting method, and epitaxial thin films with a controllable doping concentration can be prepared by methods such as mist Chemical Vapor Deposition (mist-CVD), Molecular Beam Epitaxy (MBE), Metal-organic Chemical Vapor Deposition (MOCVD), and Hydride Vapor Phase Epitaxy (HVPE). Therefore, β-Ga₂O₃ is low in cost and has been widely used in the preparation of transistors and diode devices.

β-Ga₂O₃ has a band gap of 4.9 eV, a breakdown field strength of 8 MV/cm, and a Baliga's Figure of Merit as high as 3444, which can effectively enhance the breakdown voltage of the devices and reduce energy loss. Due to its excellent physical properties, metastable-phase Ga₂O₃ has attracted much attention recently. Among them, κ-Ga₂O₃ possesses spontaneous polarization properties, which can induce the formation of a high-concentration two-dimensional electron gas at heterointerfaces, enabling high-mobility transistors. However, the lack of homo-substrates necessitates preparation via heteroepitaxy, greatly limiting its device applications.

Research on Ga₂O₃ devices is abundant in the field of power electronics, yet remains insufficient in the field of critically important inverters and logic circuits. Due to the lack of effective p-type doping in β-Ga₂O₃, conventional Complementary Metal Oxide Semiconductor (CMOS) inverters cannot be directly applied, and the preparation process thereof is relatively complex and difficult to implement. Therefore, unipolar inverters require more in-depth research to avoid the difficulty of p-type doping and expand further applications of Ga₂O₃ materials in circuits.

### SUMMARY

An objective of the present invention is to provide a heterogeneously integrated Ga₂O₃ high-mobility inverter and a preparation method thereof, for overcoming the deficiencies of the prior art. According to the present invention, the κ-(AlₓGa₁₋ₓ)₂O₃/κ-Ga₂O₃ layer and the β-Ga₂O₃ layer are heterogeneously integrated, and by using the high-mobility characteristics of the layers and by adopting a p-type hetero-material as an enhancement-mode gate medium, an enhancement-mode device is obtained, thereby achieving functions of an inverter and expanding its application in the field of logic circuits.

To achieve the above objective, the present invention designs the following technical solution:

A heterogeneously integrated Ga₂O₃ high-mobility inverter, which includes a semi-insulating β-Ga₂O₃ substrate, an unintentionally doped β-Ga₂O₃ drift layer, a κ-Ga₂O₃ layer and a κ-(AlₓGa₁₋ₓ)₂O₃ layer sequentially arranged from bottom to top, and an isolation trench is arranged in the middle of the unintentionally doped β-Ga₂O₃ drift layer, the κ-Ga₂O₃ layer and the κ-(AlₓGa₁₋ₓ)₂O₃ layer;

The upper surface region of the κ-(AlₓGa₁₋ₓ)₂O₃ layer is divided into a depletion-mode device region and an enhancement-mode device region by the isolation trench;

In the depletion-mode device region, a depletion-mode drain region, a depletion-mode gate region, and a depletion-mode source region are sequentially arranged from far to near relative to the isolation trench; and in the enhancement-mode device region, an enhancement-mode source region, an enhancement-mode gate region, and an enhancement-mode drain region are sequentially arranged from far to near relative to the isolation trench.

from far to near the isolation trench, a depletion-mode drain metal layer, a depletion-mode gate metal layer, and a depletion-mode source metal layer are sequentially arranged on the depletion-mode device region;

the depletion-mode drain metal layer, the depletion-mode gate metal layer, and the depletion-mode source metal layer are arranged in the depletion-mode drain region, the depletion-mode gate region, and the depletion-mode source region, respectively;

from far to near the isolation trench, an enhancement-mode source metal layer, a p-type hetero-material and enhancement-mode gate metal combination layer, and an enhancement-mode drain metal layer are sequentially arranged on the enhancement-mode device region; and the p-type hetero-material and enhancement-mode gate metal combination layer is composed of the p-type hetero-material layer at a lower layer and the enhancement-mode gate metal layer at an upper layer;

the enhancement-mode source metal layer, the p-type hetero-material and enhancement-mode gate metal combination layer, and the enhancement-mode drain metal layer are arranged in the enhancement-mode source region, the enhancement-mode gate region, and the enhancement-mode drain region, respectively; and

the depletion-mode source metal layer is interconnected with the enhancement-mode drain metal layer, and the depletion-mode source metal layer is interconnected with the depletion-mode gate metal layer.

Further, surfaces of the depletion-mode drain metal layer, the depletion-mode source metal layer, the depletion-mode gate metal layer, the enhancement-mode gate metal layer, the enhancement-mode drain metal layer, and the enhancement-mode source metal layer are all provided with pads; and

the depletion-mode source metal layer and the enhancement-mode drain metal layer are arranged at two edges of the isolation trench, respectively; or the depletion-mode source metal layer and the enhancement-mode drain metal layer are extended and arranged on a surface of the isolation trench.

Yet further, the depletion-mode drain metal layer, the depletion-mode source metal layer, the enhancement-mode drain metal layer, and the enhancement-mode source metal layer are a Ti metal layer, an Au metal layer, and an Ni metal layer sequentially arranged from bottom to top; and the Ti layer, the Au layer, and the Ni layer have thicknesses of 20-100 nm, 50-150 nm, and 50-150 nm, respectively;

the p-type hetero-material layer consists of a material selected from the group consisting of p-NiO, p-GaN, and p-SnO;

the depletion-mode gate metal layer and the enhancement-mode gate metal layer are composed of a Pt metal layer and an Au metal layer sequentially arranged from bottom to top, the Pt layer and the Au layer have thicknesses of 150-250 nm and 200-300 nm, respectively; and

the pads are composed of a Ti metal layer and an Au metal layer sequentially arranged from bottom to top, and the Ti layer and the Au layer have thicknesses of 150-250 nm and 200-300 nm, respectively.

Yet further, in the depletion-mode drain metal layer, the depletion-mode source metal layer, the enhancement-mode drain metal layer, and the enhancement-mode source metal layer, the Ti layer, the Au layer, and the Ni layer have thicknesses of 50 nm, 100 nm, and 100 nm, respectively;

the p-type hetero-material is p-NiO;

in the depletion-mode gate metal layer and the enhancement-mode gate metal layer, the Pt layer and the Au layer have thicknesses of 150-250 nm and 200-300 nm, respectively; and

in the pads, the Ti layer and the Au layer have thicknesses of 150-250 nm and 200-300 nm, respectively.

Yet further, the unintentionally doped β-Ga₂O₃ drift layer has a thickness of 50-200 nm, the κ-(AlₓGa₁₋ₓ)₂O₃ layer has a thickness of 10-50 nm, and the κ-Ga₂O₃ layer has a thickness of 20-50 nm.

Yet further, the unintentionally doped β-Ga₂O₃ drift layer has a thickness of 150 nm, the κ-(AlₓGa₁₋ₓ)₂O₃ layer has a thickness of 20 nm, and the κ-Ga₂O₃ layer has a thickness of 30 nm.

The present invention further provides a preparation method for preparing the above-mentioned inverter, including the following steps:

S1: preparing an unintentionally doped β-Ga₂O₃ drift layer on a semi-insulating β-Ga₂O₃ substrate by MOCVD;

S2: sequentially preparing a κ-Ga₂O₃ layer and a κ-(AlₓGa₁₋ₓ)₂O₃ layer on a surface of the unintentionally doped β-Ga₂O₃ drift layer by lift-off and transfer technology or an epitaxial growth, and forming a two-dimensional electron gas between the κ-Ga₂O₃ layer and the κ-(AlₓGa₁₋ₓ)₂O₃ layer in a polarization-induced manner;

S3: etching a middle portion of a surface of the κ-(AlₓGa₁₋ₓ)₂O₃ layer by Reactive Ion Etching-Inductively Coupled Plasma (RIE-ICP) etching until reaching a surface of the semi-insulating β-Ga₂O₃ substrate, so as to form an isolation trench;

S4: defining a depletion-mode drain region, a depletion-mode source region, an enhancement-mode drain region, and an enhancement-mode source region on the surface of the κ-(AlₓGa₁₋ₓ)₂O₃ layer by using photolithography; and sequentially growing a Ti metal layer, an Au metal layer, and an Ni metal layer by electron beam evaporation to form a depletion-mode drain metal layer, a depletion-mode source metal layer, an enhancement-mode drain metal layer, and an enhancement-mode source metal layer, wherein the depletion-mode drain metal layer, the depletion-mode source metal layer, the enhancement-mode drain metal layer, and the enhancement-mode source metal layer form ohmic contacts with the κ-(AlₓGa₁₋ₓ)₂O₃ layer, respectively;

S5: defining a depletion-mode gate region on the surface of the κ-(AlₓGa₁₋ₓ)₂O₃ layer by using the photolithography; and sequentially growing a Pt metal layer and an Au metal layer by electron beam evaporation to form a depletion-mode gate metal layer, wherein the depletion-mode gate metal layer forms a Schottky contact with the κ-(AlₓGa₁₋ₓ)₂O₃ layer;

S6: defining an enhancement-mode gate region on the surface of the κ-(AlₓGa₁₋ₓ)₂O₃ layer by using the photolithography, and growing a p-type hetero-material layer by magnetron sputtering;

S7: sequentially growing a Pt metal layer and an Au metal layer on a surface of the p-type hetero-material layer by means of self-alignment by electron beam evaporation, so as to form an enhancement-mode gate metal layer; and

S8: sequentially growing a Ti metal layer and an Au metal layer on the depletion-mode drain metal layer, the depletion-mode source metal layer, the depletion-mode gate metal layer, the enhancement-mode drain metal layer, the enhancement-mode source metal layer, and the enhancement-mode gate metal layer respectively by electron beam evaporation, so as to form pads, wherein the depletion-mode source metal layer and the enhancement-mode drain metal layer are interconnected via the pads and are jointly connected to the depletion-mode gate metal layer, so as to obtain the heterogeneously integrated Ga₂O₃ high-mobility inverter.

Further, the lift-off and transfer technology in the step S2 specifically includes the following steps:

1) sequentially growing a κ-Ga₂O₃ layer with a thickness of 100-200 nm, a κ-(AlₓGa₁₋ₓ)₂O₃ layer with a thickness of 100-500 nm, and a κ-Ga₂O₃ layer with a thickness of 20-50 nm on a sapphire substrate from bottom to top by tin-assisted pulsed laser deposition;

2) implanting hydrogen ions into the κ-(AlₓGa₁₋ₓ)₂O₃ layer, and bonding the κ-Ga₂O₃ layer with the thickness of 20-50 nm to the unintentionally doped β-Ga₂O₃ drift layer by using a bonding machine; and

3) finally, separating the κ-Ga₂O₃ layer with the thickness of 100-200 nm and the sapphire substrate from the κ-(AlₓGa₁₋ₓ)₂O₃ layer by means of high-temperature annealing, and smoothing and polishing the surface of the κ-(AlₓGa₁₋ₓ)₂O₃ layer to a thickness of 10-50 nm.

Yet further, conditions for the high-temperature annealing are: an annealing temperature of 1100° C, and an annealing duration of 30-60 minutes.

Yet further, in the depletion-mode drain metal layer, the depletion-mode source metal layer, the enhancement-mode drain metal layer, and the enhancement-mode source metal layer, the Ti layer, the Au layer, and the Ni layer have thicknesses of 20-100 nm, 50-150 nm, and 50-150 nm, respectively;

the p-type hetero-material layer consists of a material selected from the group consisting of p-NiO, p-GaN, and p-SnO;

in the depletion-mode gate metal layer and the enhancement-mode gate metal layer, the Pt layer and the Au layer have thicknesses of 150-250 nm and 200-300 nm, respectively;

in the pads, the Ti layer and the Au layer have thicknesses of 150-250 nm and 200-300 nm, respectively; and

the unintentionally doped β-Ga₂O₃ drift layer has a thickness of 50-200 nm, the κ-(AlₓGa₁₋ₓ)₂O₃ layer has a thickness of 10-50 nm, and the κ-Ga₂O₃ layer has a thickness of 20-50 nm.

The present invention has the following beneficial effects:

1. The gallium oxide inverter designed by the present invention adopts monolithically integrated depletion-mode and enhancement-mode devices, and is simple in preparation process and effectively broadens the prospects of gallium oxide devices in logic circuits compared to Complementary Metal Oxide Semiconductor (CMOS) inverters.

2. The β-Ga₂O₃ substrate can be grown by using a melting method with low cost, and epitaxial thin films thereof can be prepared by various methods. However, as a metastable-phase Ga₂O₃ material, κ-Ga₂O₃ lacks a homo-substrate and high-quality epitaxial thin films, limiting its application in devices. By means of heterogeneous integration, the difficulty of applying κ-Ga₂O₃ in the devices can be alleviated, and its excellent characteristics (such as polarization characteristics) can be reasonably applied in the devices.

3. According to the present invention, a polarization-induced two-dimensional electron gas exists at an interface between the κ-(AlₓGa₁₋ₓ)₂O₃ layer and the κ-Ga₂O₃ layer, with an electron mobility much higher than that of a β-Ga₂O₃ bulk material. Its high mobility enables inverters with high switching speed, which can be subsequently applied in high-speed circuits and other fields.

4. According to the present invention, the p-type hetero-material is adopted as an enhancement-mode gate medium, which solves the problem that Ga₂O₃ material can hardly be p-type doped, thereby obtaining an enhancement-mode Ga₂O₃ high-mobility transistor and laying a foundation for its subsequent applications in other circuits.

### BRIEF DESCRIPTION OF THE DRAWINGS

FIG. 1 shows a schematic structural diagram of a heterogeneously integrated Ga₂O₃ high-mobility inverter;

FIG. 2 shows a schematic diagram of steps for preparing a semi-insulating β-Ga₂O₃ substrate and an unintentionally doped β-Ga₂O₃ drift layer;

FIG. 3 shows a schematic structural diagram of a κ-Ga₂O₃/κ-(AlₓGa₁₋ₓ)₂O₃/κ-Ga₂O₃ layer;

FIG. 4 shows a flow diagram of transferring the κ-Ga₂O₃/κ-(AlₓGa₁₋ₓ)₂O₃/κ-Ga₂O₃ layer;

FIG. 5 shows a schematic diagram of forming an isolation trench between devices;

FIG. 6 shows a schematic diagram of preparing source metal layer and drain metal layer;

FIG. 7 shows a schematic diagram of preparing a depletion-mode gate metal layer;

FIG. 8 shows a schematic diagram of preparing a p-type hetero-material layer;

FIG. 9 shows a schematic diagram of preparing an enhancement-mode gate metal layer;

FIG. 10 shows a schematic diagram of implementing interconnection between the devices;

FIG. 11 shows a structural diagram of an energy band for the heterogeneously integrated Ga₂O₃ high-mobility inverter;

FIG. 12 shows a simulation result diagram of electron mobilities for κ-Ga₂O₃/β-Ga₂O₃;

FIG. 13 shows a simulation result diagram of transfer characteristics of a depletion-mode device;

FIG. 14 shows a simulation result diagram of transfer characteristics of an enhancement-mode device; and

FIG. 15 shows a simulation result diagram of voltage transfer characteristics of the heterogeneously integrated Ga₂O₃ high-mobility inverter.

In the figures: 1. semi-insulating β-Ga₂O₃ substrate; 2. unintentionally doped β-Ga₂O₃ drift layer; 3. κ-(AlₓGa₁₋ₓ)₂O₃ layer; 4. κ-Ga₂O₃ layer; 5. p-type hetero-material layer; 6. depletion-mode drain metal layer; 7. depletion-mode source metal layer; 8. depletion-mode gate metal layer; 9. enhancement-mode drain metal layer; 10. enhancement-mode source metal layer; 11. enhancement-mode gate metal layer; 12. sapphire substrate; 13. pad; and 14. isolation trench.

### DETAILED DESCRIPTION OF THE EMBODIMENTS

The present invention is further described below in detail with reference to specific examples, facilitating understanding by those skilled in the art.

### Example 1

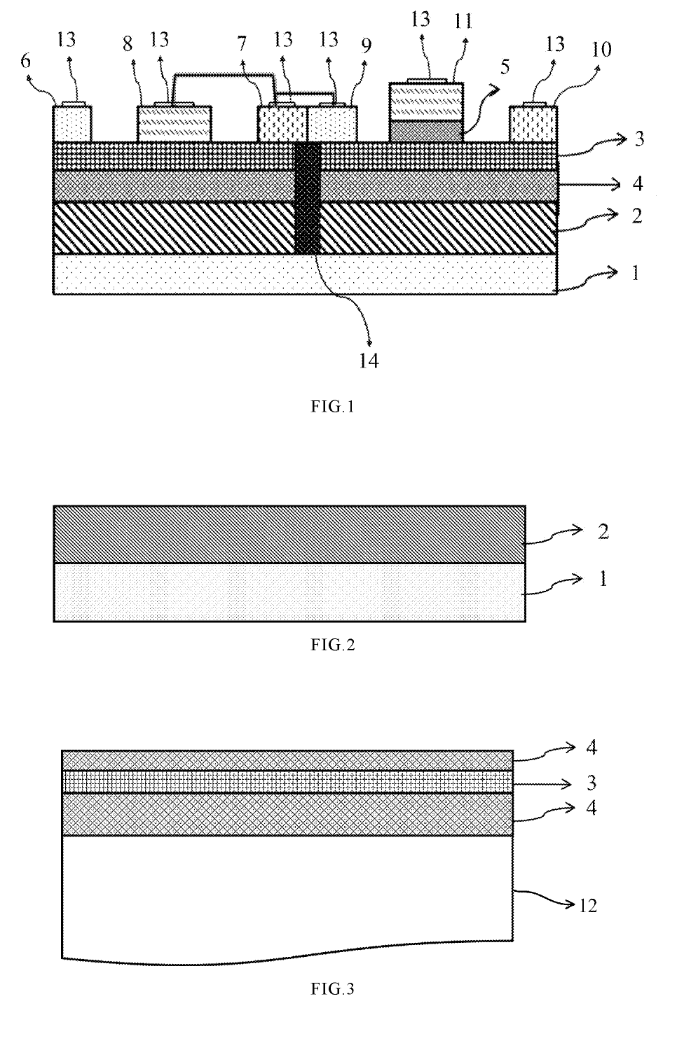

This example provides a heterogeneously integrated Ga₂O₃ high-mobility inverter. As shown in FIG. 1, the inverter includes a semi-insulating β-Ga₂O₃ substrate 1, an unintentionally doped β-Ga₂O₃ drift layer 2, a κ-Ga₂O₃ layer 4, and a κ-(AlₓGa₁₋ₓ)₂O₃ layer 3 that are sequentially arranged from bottom to top. An isolation trench 14 is arranged in the middle of the unintentionally doped β-Ga₂O₃ drift layer 2, the κ-Ga₂O₃ layer 4, and the κ-(AlₓGa₁₋ₓ)₂O₃ layer 3.

An upper surface region of the κ-(AlₓGa₁₋ₓ)₂O₃ layer 3 is divided into a depletion-mode device region and an enhancement-mode device region by the isolation trench 14.

From far to near the isolation trench 14, a depletion-mode drain metal layer 6, a depletion-mode gate metal layer 8, and a depletion-mode source metal layer 7 are sequentially arranged on the depletion-mode device region.

From far to near the isolation trench 14, an enhancement-mode source metal layer 10, a p-type hetero-material and enhancement-mode gate metal combination layer, and an enhancement-mode drain metal layer 9 are sequentially arranged on the enhancement-mode device region. The p-type hetero-material and enhancement-mode gate metal combination layer is composed of the p-type hetero-material layer 5 at a lower layer and the enhancement-mode gate metal layer 11 at an upper layer.

The depletion-mode source metal layer 7 is interconnected with the enhancement-mode drain metal layer 9, and the depletion-mode source metal layer 7 is interconnected with the depletion-mode gate metal layer 8.

Surfaces of the depletion-mode drain metal layer 6, the depletion-mode source metal layer 7, the depletion-mode gate metal layer 8, the enhancement-mode gate metal layer 11, the enhancement-mode drain metal layer 9, and the enhancement-mode source metal layer 10 are all provided with pads 13.

The depletion-mode source metal layer 7 and the enhancement-mode drain metal layer 9 are arranged at two edges of the isolation trench 14, respectively; or the depletion-mode source metal layer 7 and the enhancement-mode drain metal layer 9 are extended and arranged on a surface of the isolation trench 14.

In the heterogeneously integrated Ga₂O₃ high-mobility inverter of this embodiment:

(1) the depletion-mode drain metal layer 6, the depletion-mode source metal layer 7, the enhancement-mode drain metal layer 9, and the enhancement-mode source metal layer 10 are composed of a Ti metal layer, an Au metal layer and an Ni metal layer sequentially arranged from bottom to top; and the Ti layer, the Au layer, and the Ni layer have thicknesses of 20-100 nm, 50-150 nm, and 50-150 nm, respectively;

the p-type hetero-material layer 5 consists of a material selected from the group consisting of p-NiO, p-GaN, and p-SnO;

the depletion-mode gate metal layer 8 and the enhancement-mode gate metal layer 11 are composed of a Pt metal layer and an Au metal layer sequentially arranged from bottom to top, the Pt metal layer has a thickness of 150-250 nm, and the Au metal layer has a thickness of 200-300 nm; and

the pads 13 are composed of a Ti metal layer and an Au metal layer sequentially arranged from bottom to top, and the Ti layer and the Au layer have thicknesses of 150-250 nm and 200-300 nm, respectively.

Preferably, in the depletion-mode drain metal layer 6, the depletion-mode source metal layer 7, the enhancement-mode drain metal layer 9, and the enhancement-mode source metal layer 10, the Ti layer, the Au layer, and the Ni layer have thicknesses of 50 nm, 100 nm, and 100 nm, respectively;

the p-type hetero-material layer 5 consists of p-NiO;

in the depletion-mode gate metal layer 8 and the enhancement-mode gate metal layer 11, the Pt layer and the Au layer have thicknesses of 200 nm and 250 nm, respectively;

in the pads 13, the Ti layer and the Au layer have thicknesses of 200 nm and 250 nm, respectively.

(2) The unintentionally doped β-Ga₂O₃ drift layer 2 has a thickness of 50-200 nm, the κ-(AlₓGa₁₋ₓ)₂O₃ layer 3 has a thickness of 10-50 nm, and the κ-Ga₂O₃ layer 4 has a thickness of 20-50 nm.

Preferably, the unintentionally doped β-Ga₂O₃ drift layer 2 has a thickness of 150 nm, the κ-(AlₓGa₁₋ₓ)₂O₃ layer 3 has a thickness of 20 nm, and the κ-Ga₂O₃ layer 4 has a thickness of 30 nm.

### Example 2

This example provides a preparation method of the heterogeneously integrated Ga₂O₃ high-mobility inverter of Example 1. As shown in FIGS. 2 to 10, the preparation method comprises the following steps:

1. As shown in FIG. 2, an unintentionally doped β-Ga₂O₃ drift layer 2 with a thickness of 50-200 nm is prepared on a semi-insulating β-Ga₂O₃ substrate 1 by MOCVD.

2. As shown in FIG. 3, a κ-Ga₂O₃ layer 4 with a thickness of 100-200 nm, a κ-(AlₓGa₁₋ₓ)₂O₃ layer 3 with a thickness of 100-500 nm, and a κ-Ga₂O₃ layer 4 with a thickness of 20-50 nm are sequentially grown based on a sapphire substrate 12 from bottom to top by tin-assisted pulsed laser deposition.

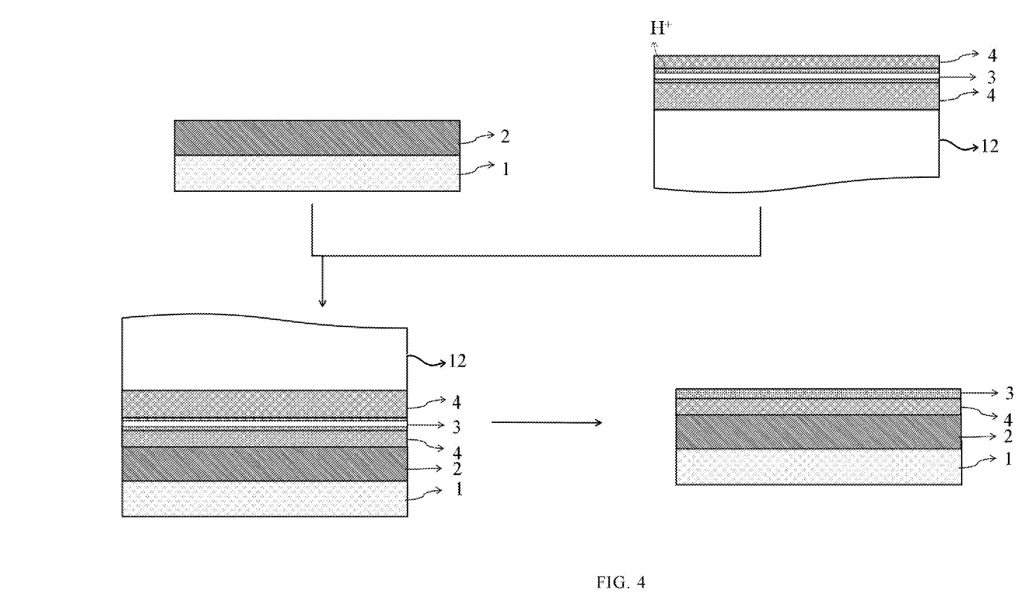

3. As shown in FIG. 4, H^{⁺} is implanted into the κ-(AlₓGa₁₋ₓ)₂O₃ layer 3 by using an ion implanter. The κ-Ga₂O₃ layer 4 with a thickness of 20-50 nm is bonded to the unintentionally doped β-Ga₂O₃ drift layer 2 by using a bonding machine combined with lift-off and transfer technology. Finally, the κ-Ga₂O₃ layer 4 with a thickness of 100-200 nm at an upper layer and the sapphire substrate 12 are separated from the κ-(AlₓGa₁₋ₓ)₂O₃ layer 3 by means of high-temperature annealing, where conditions for the high-temperature annealing are an annealing temperature of 1100° C and an annealing duration of 30-60 minutes. A surface of the κ-(AlₓGa₁₋ₓ)₂O₃ layer 3 is smoothed and polished to a thickness of 10-50 nm by means of chemical mechanical polishing. The κ-(AlₓGa₁₋ₓ)₂O₃ layer 3 is located at a top end of the κ-Ga₂O₃ layer 4, and a two-dimensional electron gas is formed at an interface between the two layers in a polarization-induced manner.

4. As shown in FIG. 5, after photolithographic patterning is performed, a sample is etched by RIE-ICP etching until reaching a surface of the semi-insulating β-Ga₂O₃ substrate 1, thereby forming an isolation trench 14 between a depletion-mode device and an enhancement-mode device. An excess photoresist is removed with a glue remover by means of lift-off, and the sample is cleaned. Between the devices, the isolation trench 14 enables the depletion-mode device to be isolated from the enhancement-mode device.

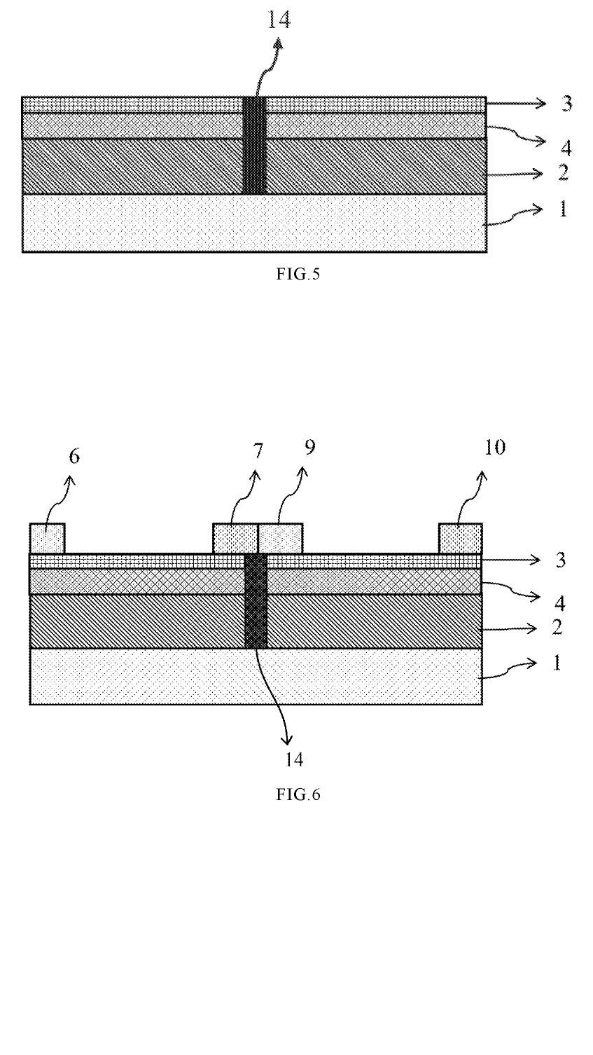

5. As shown in FIG. 6, after selecting a depletion-mode drain region, a depletion-mode source region, an enhancement-mode drain region, and an enhancement-mode source region on the surface of the κ-(AlₓGa₁₋ₓ)₂O₃ layer 3 by using photolithography, a Ti metal layer, an Au metal layer, and an Ni metal layer are sequentially grown in the depletion-mode drain region, the depletion-mode source region, the enhancement-mode drain region, and the enhancement-mode source region, respectively by electron beam evaporation, so as to form a depletion-mode drain metal layer 6, a depletion-mode source metal layer 7, an enhancement-mode drain metal layer 9, and an enhancement-mode source metal layer 10, where the Ti layer, the Au layer, and the Ni layer have thicknesses of 20-100 nm, 50-150 nm, and 50-150 nm, respectively. An excess photoresist and metal are removed with a glue remover by means of lift-off, and the sample is cleaned. Subsequently, rapid thermal annealing is performed at 800° C for 30 s, enabling the depletion-mode drain metal layer 6, the depletion-mode source metal layer 7, the enhancement-mode drain metal layer 9, and the enhancement-mode source metal layer 10 to achieve ohmic contacts with the κ-(AlₓGa₁₋ₓ)₂O₃ layer 3, respectively. In this example, the depletion-mode source metal layer 7 and the enhancement-mode drain metal layer 9 are extended and arranged on the surface of the isolation trench 14, and the depletion-mode source metal layer 7 is in contact with the enhancement-mode drain metal layer 9.

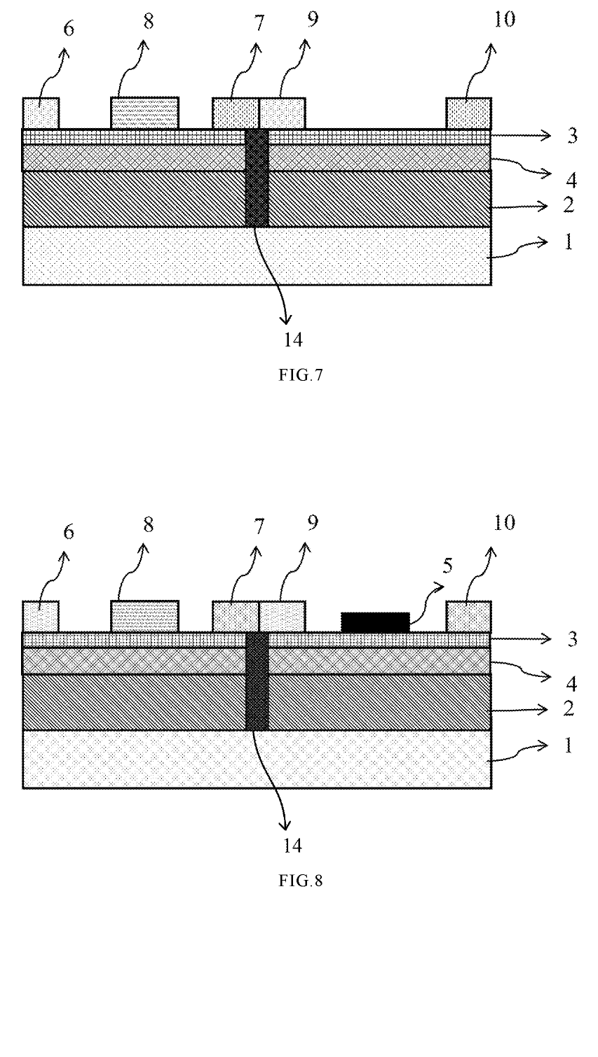

6. As shown in FIG. 7, a depletion-mode gate region is selected on the surface of the κ-(AlₓGa₁₋ₓ)₂O₃ layer 3 by using the photolithography; a Pt metal layer and an Au metal layer are sequentially grown in the depletion-mode gate region by electron beam evaporation, the Pt layer and the Au layer having thicknesses of 150-250 nm and 200-300 nm, respectively, so as to form a depletion-mode gate metal layer 8, where the depletion-mode gate metal layer 8 forms a Schottky contact with the κ-(AlₓGa₁₋ₓ)₂O₃ layer 3. An excess photoresist and metal are removed with a glue remover by means of lift-off, and the sample is cleaned.

7. As shown in FIG. 8, an enhancement-mode gate region is selected on the surface of the κ-(AlₓGa₁₋ₓ)₂O₃ layer 3 by using the photolithography, a p-type hetero-material layer 5 is grown in the enhancement-mode gate region by magnetron sputtering, and the p-type hetero-material layer 5 consists of a material selected from the group consisting of p-NiO, p-GaN, and p-SnO. The p-type hetero-material layer 5 is used to deplete carriers under a gate to form an enhancement-mode device.

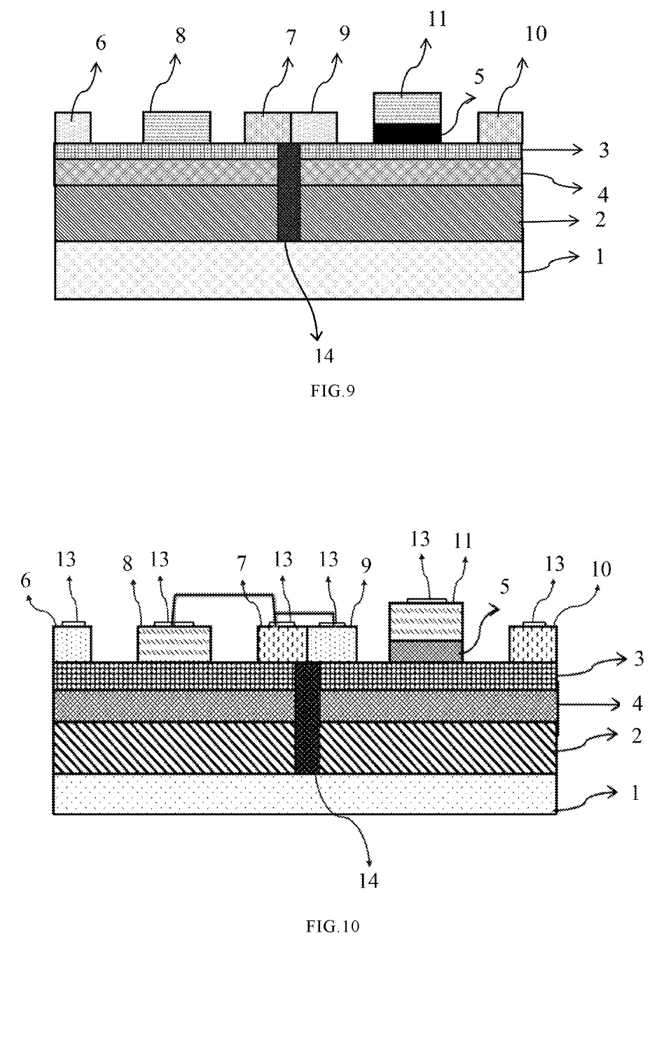

8. As shown in FIG. 9, a Pt metal layer and an Au metal layer are sequentially grown on a surface of the p-type hetero-material layer 5 by means of self-alignment by electron beam evaporation, the Pt layer and the Au layer having thicknesses of 150-250 nm and 200-300 nm, respectively, so as to form an enhancement-mode gate metal layer 11. An excess photoresist and metal are removed with a glue remover by means of lift-off, and the sample is cleaned.

9. As shown in FIG. 10, after pad regions are selected by using the photolithography, a Ti metal layer and an Au metal layer are sequentially grown on the depletion-mode drain metal layer 6, the depletion-mode source metal layer 7, the depletion-mode gate metal layer 8, the enhancement-mode drain metal layer 9, the enhancement-mode source metal layer 10, and the enhancement-mode gate metal layer 11, respectively by electron beam evaporation, so as to form pads 13, where the Ti layer and the Au layer have thicknesses of 150-250 nm and 200-300 nm, respectively. The depletion-mode source metal layer 7 and the enhancement-mode drain metal layer 9 are interconnected by the pad, and the depletion-mode source metal layer 7 is interconnected with the depletion-mode gate metal layer 8 (with the depletion-mode source metal layer 7 and the enhancement-mode drain metal layer 9 jointly connected to the depletion-mode gate metal layer 8), achieving interconnection between the devices. An excess photoresist and metal are removed with a glue remover by means of lift-off and transfer technology, and the sample is cleaned. Finally, the heterogeneously integrated Ga₂O₃ high-mobility inverter is prepared.

### Example 3

This example provided a preparation method of a heterogeneously integrated Ga₂O₃ high-mobility inverter. The preparation method is the same as that of Example 2, differing only in that methods for preparing the κ-Ga₂O₃ layer 4 and the κ-(AlₓGa₁₋ₓ)₂O₃ layer 3 (i.e., the steps2 and 3 in Example 2) are different. The method for preparing the κ-Ga₂O₃ layer 4 and the κ-(AlₓGa₁₋ₓ)₂O₃ layer 3 in this embodiment is as follows:

sequentially epitaxially growing a 20-50 nm κ-Ga₂O₃ layer 4 and a 10-50 nm κ-(AlₓGa₁₋ₓ)₂O₃ layer 3 on the unintentionally doped β-Ga₂O₃ drift layer 2, and forming a two-dimensional electron gas at an interface between the κ-(AlₓGa₁₋ₓ)₂O₃ layer 3 and the κ-Ga₂O₃ layer 4 in a polarization-induced manner.

### Example 4

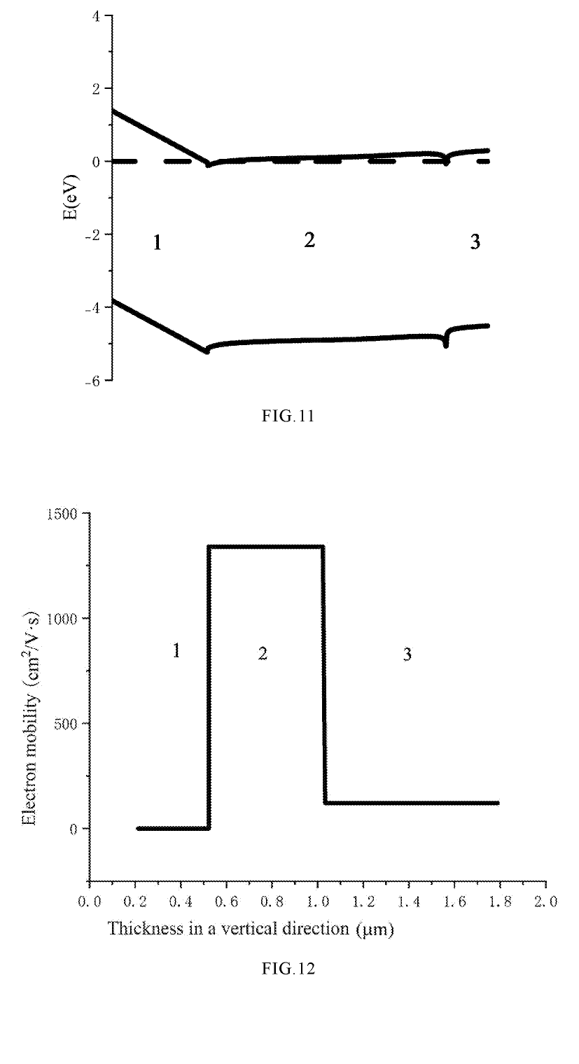

1. The heterogeneously integrated Ga₂O₃high-mobility inverter of Example 1is simulated by using Silvaco TCAD simulation software, and a structural diagram of an energy band thereof is extracted, as shown in FIG. 11. In the figure, reference numeral 1 denotes the κ-(AlₓGa₁₋ₓ)₂O₃ layer, reference numeral 2 denotes the κ-Ga₂O₃ layer, and reference numeral 3 denotes the β-Ga₂O₃ layer. A two-dimensional electron gas is generated at the interface between the κ-(AlₓGa₁₋ₓ)₂O₃ layer and the κ-Ga₂O₃ layer in a polarization-induced manner, exhibiting a relatively high mobility, as shown in FIG. 12. In the figure, reference numeral 1 denotes the mobility of the κ-(AlₓGa₁₋ₓ)₂O₃ layer, reference numeral 2 denotes the mobility of the two-dimensional electron gas in the κ-Ga₂O₃ layer, and reference numeral 3 denotes the mobility of the β-Ga₂O₃ layer. Consequently, the inverter possesses high switching speed.

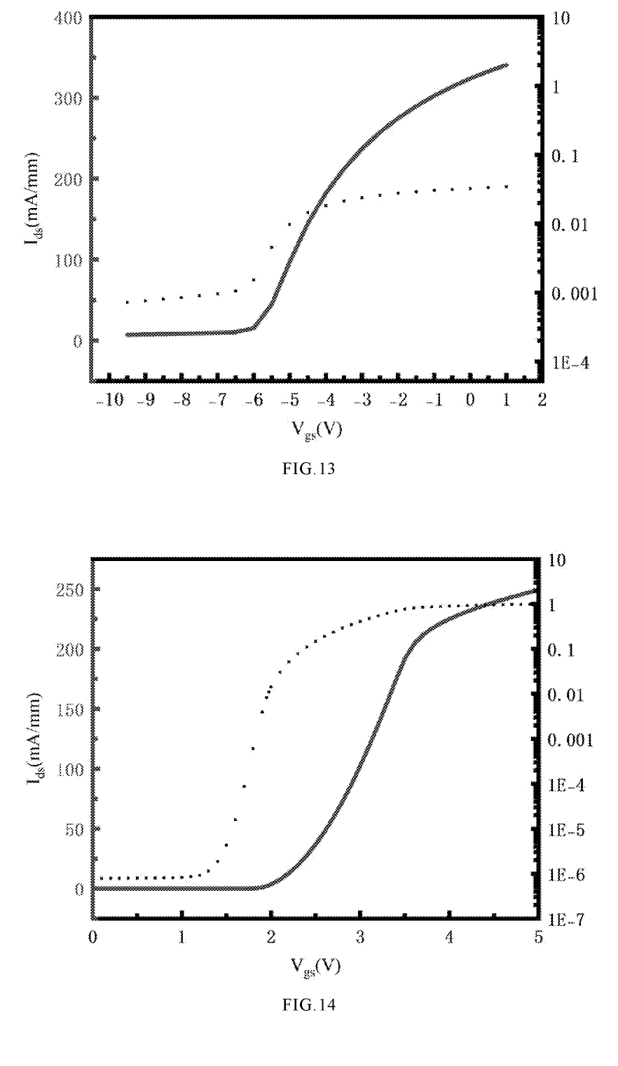

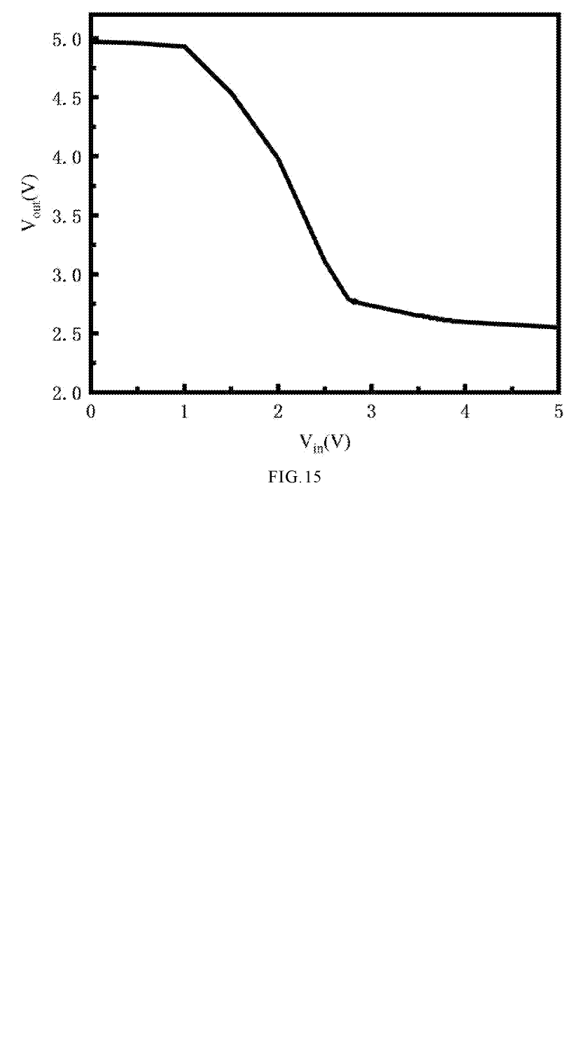

2. The transfer characteristics of the depletion-mode device and the enhancement-mode device in the heterogeneously integrated Ga₂O₃ high-mobility inverter of Example 1 are analyzed, as shown in FIGS. 13 and 14. A threshold voltage of the depletion-mode device is approximately -5.8 V, and a threshold voltage of the enhancement-mode device is approximately 2 V, demonstrating that the structural design of this solution can implement a monolithically integrated inverter.

3. The voltage transfer characteristics of the heterogeneously integrated Ga₂O₃ high-mobility inverter of Example 1 are analyzed. As shown in FIG. 15, when an input voltage Vᵢₙ switches from a low voltage to a high voltage, an output voltage Vₒᵤₜ switches from a high voltage to a low voltage, thereby realizing a logic inversion function.

All other parts not elaborated in detail belong to the prior art. Although the aforementioned examples provide a detailed description of the present invention, they are merely some rather than all of the examples of the present invention. Those skilled in the art can derive other examples from these examples without creative effort, and all such examples shall fall within the scope of protection of the present invention.

What is claimed is:

1. A preparation method of a heterogeneously integrated Ga₂O₃ high-mobility inverter, comprising the following steps:
S1: preparing an unintentionally doped β-Ga₂O₃ drift layer on a semi-insulating β-Ga₂O₃ substrate by metal-organic chemical vapor deposition (MOCVD);
S2: sequentially preparing a κ-Ga₂O₃ layer and a κ-(AlₓGa₁₋ₓ)₂O₃ layer on a surface of the unintentionally doped β-Ga₂O₃ drift layer by lift-off and transfer technology or epitaxial growth, and forming a two-dimensional electron gas between the κ-Ga₂O₃ layer and the κ-(AlₓGa₁₋ₓ)₂O₃ layer in a polarization-induced manner;
S3: etching a middle portion of a surface of the κ-(AlₓGa₁₋ₓ)₂O₃ layer by reactive ion etching-inductively coupled plasma (RIE-ICP) etching until reaching a surface of the semi-insulating β-Ga₂O₃ substrate, so as to form an isolation trench;
S4: defining a depletion-mode drain region, a depletion-mode source region, an enhancement-mode drain region, and an enhancement-mode source region on the surface of the κ-(AlₓGa₁₋ₓ)₂O₃ layer by photolithography; and sequentially growing a Ti metal layer, an Au metal layer, and an Ni metal layer by electron beam evaporation to form a depletion-mode drain metal layer, a depletion-mode source metal layer, an enhancement-mode drain metal layer, and an enhancement-mode source metal layer, wherein the depletion-mode drain metal layer, the depletion-mode source metal layer, the enhancement-mode drain metal layer, and the enhancement-mode source metal layer form ohmic contacts with the κ-(AlₓGa₁₋ₓ)₂O₃ layer, respectively;
S5: defining a depletion-mode gate region on the surface of the κ-(AlₓGa₁₋ₓ)₂O₃ layer by photolithography; and sequentially growing a Pt metal layer and an Au metal layer by electron beam evaporation to form a depletion-mode gate metal layer, wherein the depletion-mode gate metal layer forms a Schottky contact with the κ-(AlₓGa₁₋ₓ)₂O₃ layer;
S6: defining an enhancement-mode gate region on the surface of the κ-(AlₓGa₁₋ₓ)₂O₃ layer by photolithography, and growing a p-type hetero-material layer by magnetron sputtering;
S7: sequentially growing a Pt metal layer and an Au metal layer on a surface of the p-type hetero-material layer by means of self-alignment by electron beam evaporation, so as to form an enhancement-mode gate metal layer;
S8: sequentially growing a Ti metal layer and an Au metal layer on the depletion-mode drain metal layer, the depletion-mode source metal layer, the depletion-mode gate metal layer, the enhancement-mode drain metal layer, the enhancement-mode source metal layer, and the enhancement-mode gate metal layer respectively by electron beam evaporation, so as to form pads, wherein the depletion-mode source metal layer and the enhancement-mode drain metal layer are interconnected via the pads and are jointly connected to the depletion-mode gate metal layer, so as to obtain the heterogeneously integrated Ga₂O₃ high-mobility inverter.

2. The method according to claim 1, wherein the lift-off and transfer technology in the step S2 specifically comprises the following steps:
1) sequentially growing a κ-Ga₂O₃ layer with a thickness of 100-200 nm, a κ-(AlₓGa₁₋ₓ)₂O₃ layer with a thickness of 100-500 nm, and a κ-Ga₂O₃ layer with a thickness of 20-50 nm on a sapphire substrate from bottom to top by tin-assisted pulsed laser deposition;
2) implanting hydrogen ions into the κ-(AlₓGa₁₋ₓ)₂O₃ layer, and bonding the κ-Ga₂O₃ layer with the thickness of 20-50 nm to the unintentionally doped β-Ga₂O₃ drift layer by using a bonding machine;
3) finally, separating the κ-Ga₂O₃ layer with the thickness of 100-200 nm and the sapphire substrate from the κ-(AlₓGa₁₋ₓ)₂O₃ layer by means of high-temperature annealing, and smoothing and polishing the surface of the κ-(AlₓGa₁₋ₓ)₂O₃ layer to a thickness of 10-50 nm.

3. The method according to claim 2, wherein conditions for the high-temperature annealing are: an annealing temperature of 1100 ℃, and an annealing duration of 30-60 minutes.

4. The method according to claim 1, wherein in the depletion-mode drain metal layer, the depletion-mode source metal layer, the enhancement-mode drain metal layer, and the enhancement-mode source metal layer, the Ti layer, the Au layer, and the Ni layer have thicknesses of 20-100 nm, 50-150 nm, and 50-150 nm, respectively;
the p-type hetero-material layer consists of a material selected from the group consisting of p-NiO, p-GaN, and p-SnO;
in the depletion-mode gate metal layer and the enhancement-mode gate metal layer, the Pt layer and the Au layer have thicknesses of 150-250 nm and 200-300 nm, respectively;
in the pads, the Ti layer and the Au layer have thicknesses of 150-250 nm and 200-300 nm, respectively; and
the unintentionally doped β-Ga₂O₃ drift layer has a thickness of 50-200 nm, the κ-(AlₓGa₁₋ₓ)₂O₃ layer has a thickness of 10-50 nm, and the κ-Ga₂O₃ layer has a thickness of 20-50 nm.
